(19) United States
(12) Patent Application Publication
(10) Pub. No.: US 2017/0212198 A1
(43) Pub. Date: Jul. 27, 2017

(54) MAGNETIC RESONANCE SIGNAL PROCESSING METHOD, MAGNETIC RESONANCE SIGNAL PROCESSING APPARATUS AND MAGNETIC RESONANCE APPARATUS, AND PROGRAM

(71) Applicant: General Electric Company, Schenectady, NY (US)

(72) Inventors: Mitsuhiro BEKKU, Hino (JP); Yuko SUWA, Hino (JP); Munetsugu KOHARA, Hino (JP); Masanori OZAKI, Hino (JP)

(21) Appl. No.: 15/328,816

(22) PCT Filed: Jul. 22, 2015
(86) PCT No.: PCT/US2015/041568

§ 371 Date: Jan. 24, 2017

(30) Foreign Application Priority Data
Jul. 24, 2014 (JP) 2014-150544

(51) Int. Cl. G01R 33/565; G01R 33/56; G01R 33/341

(52) U.S. Cl. CPC G01R 33/5659; G01R 33/341; G01R 33/5608

(57) ABSTRACT

For the purpose of effectively suppressing shading generated in an image due to B1 inhomogeneity, there are performed an acquiring step of acquiring magnetic resonance signals simultaneously received at a body coil and a surface coil; a filtering step of applying image-based filtering for suppressing shading due to B1 inhomogeneity to a first image according to received signals from the body coil; a calculating step of calculating a sensitivity of the surface coil based on the image-based-filtered first image and a second image according to received signals from the surface coil; and a correcting step of correcting sensitivity unevenness in the second image using the sensitivity.

### CROSS-REFERENCE TO RELATED APPLICATIONS

This is a national stage application under 35 U.S.C. §371 (c) of PCT Patent Application No. PCT/US2015/041568, filed on Jul. 22, 2015, which claims priority to Japanese Patent Application No. 2014-150544, filed on Jul. 24, 2014, the disclosures of which are incorporated herein by reference in their entireties.

### BACKGROUND

Embodiments of the present invention relate to a technique for processing magnetic resonance signals.

One of known magnetic resonance imaging techniques is a method of obtaining an intended image by applying sensitivity correction to an image according to received signals from a surface coil acquired by a main scan while referring to an image according to received signals from a body coil acquired by a calibration scan.

A body coil generally has excellent spatial homogeneity of reception sensitivity but a relatively low SNR (signal-to-noise ratio) of received signals. A surface coil, on the other hand, exhibits excellent performance in receiving signals with high SNR but relatively low homogeneity of reception sensitivity.

According to the aforementioned imaging technique, it is possible to obtain an intended image having a high SNR without sensitivity unevenness by applying sensitivity correction to the image according to received signals from the surface coil having superiority in improvement of the SNR while referring to the image according to received signals from the body coil having superiority in spatial homogeneity of reception sensitivity.

Excitation RF (Radio Frequency) transmission pulses having a shorter wavelength have the property that they attenuate more easily in a living body. Accordingly, a distribution of the intensity of an RF magnetic field (B1) is somewhat inhomogeneous in a living body. This is commonly referred to as B1 inhomogeneity or RF magnetic field inhomogeneity. The B1 inhomogeneity is more significant in a higher magnetic field apparatus having a higher resonance frequency. The significant B1 inhomogeneity substantially affects magnetic resonance signals as well, resulting in a phenomenon that brightness is partially enhanced and/or diminished in a reconstructed image, which is sometimes called shading. Such shading may possibly be suppressed by applying an image-based filter. Moreover, a distribution of the intensity of the RF magnetic field in a living body has a strong tendency to vary sensitively in response to misregistration of a subject and/or a difference in scan conditions.

On the other hand, in the aforementioned imaging technique, a calibration scan and a main scan are performed at separate times. Accordingly, misregistration due to body motion of a subject may be often encountered, and scan conditions may frequently be different between the scans. The misregistration of a subject and/or difference in scan conditions result in different appearances of shading due to B1 inhomogeneity between an image based on received signals from the body coil and that based on received signals from the surface coil. This leads to improper sensitivity correction, and an additional error is introduced from the difference in shading due to B1 inhomogeneity, which may sometimes aggravate shading in a final intended image. In other words, even use of an image-based filter cannot effectively suppress shading.

From such circumstances, there is a need for a technique of obtaining an intended image by applying sensitivity correction to an image based on received signals from a surface coil while referring to an image based on received signals from a body coil, wherein shading in the intended image due to B1 inhomogeneity is effectively suppressed.

### SUMMARY

The invention in its first aspect provides a magnetic resonance signal processing method, comprising an acquiring step of acquiring magnetic resonance signals simultaneously received at a body coil and a surface coil; a filtering step of applying image-based filtering for suppressing shading due to B1 inhomogeneity to a first image according to received signals from said body coil; a calculating step of calculating a sensitivity of said surface coil based on said image-based-filtered first image and a second image according to received signals from said surface coil; and a correcting step of correcting sensitivity unevenness in said second image using said sensitivity.

The invention in its second aspect provides a magnetic resonance signal processing method, comprising an acquiring step of acquiring magnetic resonance signals simultaneously received at a body coil and a surface coil; a calculating step of calculating a sensitivity of said surface coil based on a first image according to received signals from said body coil and a second image according to received signals from said surface coil; a correcting step of correcting sensitivity unevenness in said second image using said sensitivity; and a filtering step of applying image-based filtering for suppressing shading due to B1 inhomogeneity to said corrected second image.

The invention in its third aspect provides a magnetic resonance signal processing apparatus, comprising a signal acquiring section for acquiring magnetic resonance signals simultaneously received at a body coil and a surface coil; an image-based filtering section for applying image-based filtering for suppressing shading due to B1 inhomogeneity to a first image according to received signals from said body coil; a sensitivity calculating section for calculating a sensitivity of said surface coil based on said image-based-filtered first image and a second image according to received signals from said surface coil; and a sensitivity correcting section for correcting sensitivity unevenness in said second image using said sensitivity.

The invention in its fourth aspect provides a magnetic resonance signal processing apparatus, comprising a signal acquiring section for acquiring magnetic resonance signals simultaneously received at a body coil and a surface coil; a sensitivity calculating section for calculating a sensitivity of said surface coil based on a first image according to received signals from said body coil and a second image according to received signals from said surface coil; a sensitivity correcting section for correcting sensitivity unevenness in said second image using said sensitivity; and an image-based filtering section for applying image-based filtering for suppressing shading due to B1 inhomogeneity to said corrected second image.

The invention in its fifth aspect provides the magnetic resonance signal processing apparatus in the third aspect, wherein said second image is a combined image of images from channels in said surface coil, said sensitivity calculating section calculates a sensitivity with respect to a pixel value in said combined image, and said sensitivity correcting section corrects sensitivity unevenness in said second image by dividing said second image by said sensitivity.

The invention in its sixth aspect provides the magnetic resonance signal processing apparatus in the fourth aspect, wherein said second image is a combined image of images from channels in said surface coil, said sensitivity calculating section calculates a sensitivity with respect to a pixel value in said images from channels by a complex expression, said sensitivity correcting section corrects sensitivity unevenness in said second image by substituting said sensitivity for said images from channels by a complex expression into a combination formula for said images from channels for obtaining said combined image.

The invention in its seventh aspect provides the magnetic resonance signal processing apparatus in the third aspect, wherein said image-based filter comprises any one of an SCIC (Surface Coil Intensity Correction) filter, a homomorphic filter, and an ITK-N4 Bias Field Correction filter.

The invention in its eighth aspect provides the magnetic resonance signal processing apparatus in the third aspect, wherein the intensity of a static magnetic field in simultaneously receiving said magnetic resonance signals is substantially 3 teslas or more.

The invention in its ninth aspect provides a magnetic resonance apparatus, comprising a signal receiving section for simultaneously receiving magnetic resonance signals by a body coil and a surface coil; an image-based filtering section for applying image-based filtering for suppressing shading due to B1 inhomogeneity to a first image according to received signals from said body coil; a sensitivity calculating section for calculating a sensitivity of said surface coil based on said image-based-filtered first image and a second image according to received signals from said surface coil; and a sensitivity correcting section for correcting sensitivity unevenness in said second image using said sensitivity.

The invention in its tenth aspect provides a magnetic resonance apparatus, comprising a signal receiving section for simultaneously receiving magnetic resonance signals by a body coil and a surface coil; a sensitivity calculating section for calculating a sensitivity of said surface coil based on a first image according to received signals from said body coil and a second image according to received signals from said surface coil; a sensitivity correcting section for correcting sensitivity unevenness in said second image using said sensitivity; and an image-based filtering section for applying image-based filtering for suppressing shading due to B1 inhomogeneity to said corrected second image.

The invention in its eleventh aspect provides the magnetic resonance apparatus in the ninth aspect, wherein said second image is a combined image of images from channels in said surface coil, said sensitivity calculating section calculates a sensitivity with respect to a pixel value in said combined image, and said sensitivity correcting section corrects sensitivity unevenness in said second image by dividing said second image by said sensitivity.

The invention in its twelfth aspect provides the magnetic resonance apparatus in the tenth aspect, wherein said second image is a combined image of images from channels in said surface coil, said sensitivity calculating section calculates a sensitivity with respect to a pixel value in said images from channels by a complex expression, and said sensitivity correcting section corrects sensitivity unevenness in said second image by substituting said sensitivity for said images from channels by a complex expression into a combination formula for said images from channels for obtaining said combined image.

The invention in its thirteenth aspect provides the magnetic resonance apparatus in the ninth aspect, wherein said image-based filter comprises any one of an SCIC (Surface Coil Intensity Correction) filter, a homomorphic filter, and an ITK-N4 Bias Field Correction filter.

The invention in its fourteenth aspect provides the magnetic resonance apparatus in the ninth aspect, wherein the intensity of a static magnetic field in simultaneously receiving said magnetic resonance signals is substantially 3 teslas or more.

The invention in its fifteenth aspect provides a program for causing a computer to function as the magnetic resonance signal processing apparatus in the third aspect.

The B1 inhomogeneity is sometimes referred to as RF magnetic field inhomogeneity or transmission magnetic field inhomogeneity.

The sensitivity by a complex expression as used herein is a sensitivity expressed by a real part representing the magnitude and an imaginary part representing the phase.

According to embodiments of the present invention, in obtaining an intended image by applying sensitivity correction to an image based on received signals from a surface coil while referring to an image based on received signals from a body coil, shading in the intended image due to B1 inhomogeneity may be effectively suppressed.

### BRIEF DESCRIPTION OF THE DRAWINGS

FIG. 1 is a diagram schematically showing a configuration of a magnetic resonance imaging apparatus (magnetic resonance imaging system) in accordance with an embodiment of the present invention;

FIG. 2 is a functional block diagram functionally representing a main portion of the magnetic resonance imaging apparatus;

FIG. 3 is a flow chart of imaging processing in the magnetic resonance imaging apparatus;

FIG. 4 depicts exemplary first images according to received signals from a body coil section and exemplary second images according to received signals from a surface coil section;

FIG. 5 is a conceptual diagram of processing of calculating a sensitivity;

FIG. 6 shows images representing exemplary results of shading suppression by a technique of the present embodiment; and

FIG. 7 is a flow chart of imaging processing in which an image-based filter is applied to a sensitivity-corrected image.

### DETAILED DESCRIPTION

Now an embodiment of the present invention will be described hereinbelow. The present embodiment is a magnetic resonance imaging apparatus. The magnetic resonance imaging apparatus in accordance with the present embodiment obtains an intended image by applying sensitivity correction to an image based on magnetic resonance signals received at a surface coil while referring to an image based on magnetic resonance signals received at a body coil. In the magnetic resonance imaging apparatus in accordance with the present embodiment, the magnetic resonance signals are simultaneously received by the body coil and surface coil. Moreover, in the magnetic resonance imaging apparatus in accordance with the present embodiment, in obtaining the intended image, an image-based filter is applied to a reference image based on received signals from the body coil to suppress shading due to B1 inhomogeneity, whereby shading is suppressed also in a sensitivity-corrected intended image based on received signals from the surface coil.

First, a configuration of the magnetic resonance imaging apparatus in accordance with the present embodiment will be described.

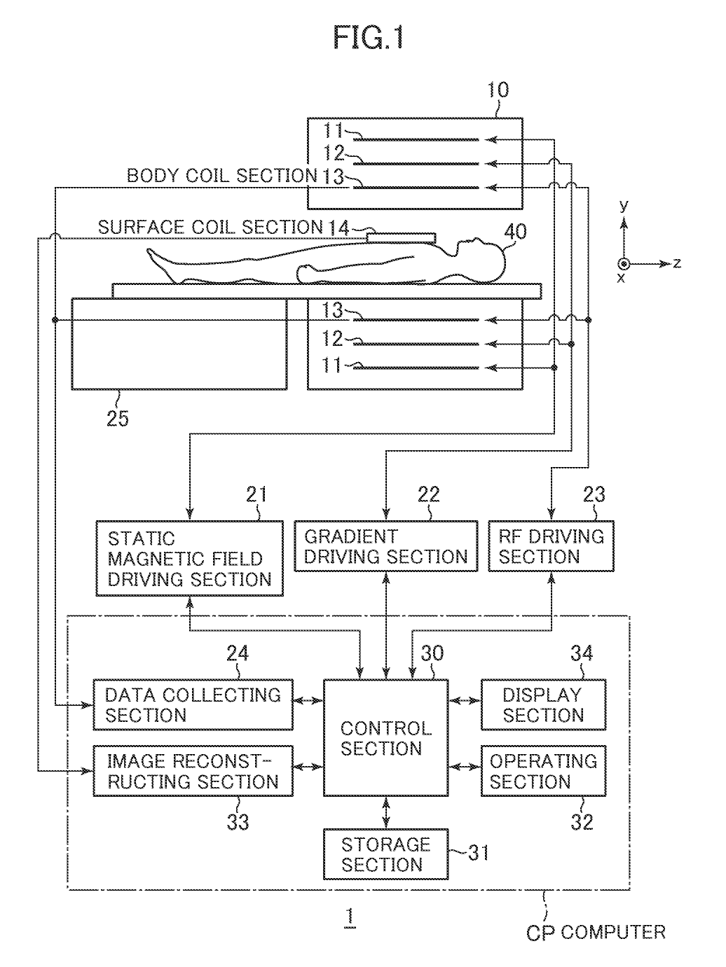

FIG. 1 is a diagram schematically showing a configuration of the magnetic resonance imaging apparatus in accordance with the present embodiment.

As shown in FIG. 1, the magnetic resonance imaging apparatus 1 comprises a static magnetic field coil section 11, a gradient coil section 12, a body coil section 13, a surface coil section 14, a static magnetic field driving section 21, a gradient driving section 22, an RF driving section 23, a data collecting section 24, a subject carrying section 25, a control section 30, a storage section 31, an operating section 32, an image reconstructing section 33, and a display section 34.

The static magnetic field coil section 11 is a superconductive coil, for example, for receiving supply of electric current, and generating a static magnetic field to create a static magnetic field space.

The gradient coil section 12 receives supply of electric current, and generates gradient magnetic fields independently in three axis directions: a slice axis direction, a phase encoding direction, and a frequency encoding direction. It should be noted that the frequency encoding direction, phase encoding direction, and slice axis direction here correspond to an x-direction, a y-direction, and a z-direction, respectively, shown in FIG. 1.

The body coil section 13 receives supply of electric current, and generates a high-frequency magnetic field, i.e., RF (radio frequency) pulses, for exciting atomic nuclear spins in a subject 40 in the static magnetic field space. The body coil section 13 also receives magnetic resonance signals from the subject 40.

The surface coil section 14 is placed on a surface of a region to be imaged in the subject 40, and it receives magnetic resonance signals from the region to be imaged. The surface coil section 14 is comprised of a plurality of channel coils. The number of channel coils, i.e., the number of channels, is of the order of 2-10, for example. The channel coil is sometimes referred to as coil element.

The static magnetic field driving section 21 drives the static magnetic field coil section 11 based on a control signal from the control section 30 to generate a static magnetic field. The intensity of the static magnetic field is assumed herein to be 3 teslas or more with which B1 inhomogeneity is noticeable.

The gradient driving section 22 drives the gradient coil section 12 based on a control signal from the control section 30 to generate (transmit) a gradient magnetic field in the static magnetic field space.

The RF driving section 23 drives the body coil section 13 based on a control signal from the control section 30 to generate (transmit) a high frequency magnetic field in the static magnetic field space.

The data collecting section 24 applies phase detection to received signals received by the body coil section 13 and surface coil section 14, and A-D (Analog-to-Digital) converts the resulting signals to generate data for the received signals. The generated data for the received signals is output to the storage section 31.

The subject carrying section 25 carries the subject 40 into/out of the static magnetic field space based on a control signal from the control section 30.

The control section 30 sends a control signal to the gradient driving section 23 for controlling it to perform gradient shimming for each subject 40 or for each region to be imaged. The control section 30 also sends control signals to the static magnetic field driving section 21, gradient driving section 22, RF driving section 23, data collecting section 24, and subject carrying section 25 for controlling them to perform a specified pulse sequence based on an operation signal from the operating section 32.

The storage section 31 stores therein the data for the received signals collected by the data collecting section 24, image data obtained by applying image reconstruction processing by the image reconstructing section 33, and the like.

The image reconstructing section 33 reads the data for the received signals from the storage section 31 by control from the control section 30, and applies image reconstruction processing to the data for the received signals to create image data. The image data is output to the storage section 31.

The display section 34 displays information required in operation of the operating section 32, an image represented by the image data, and the like.

It should be noted that the data collecting section 24, control section 30, storage section 31, operating section 32, image reconstructing section 33, and display section 34 are configured by a computer CP, for example.

Moreover, hardware measures for decoupling are applied to the body coil section 13 and surface coil section 14. For example, the impedance of preamplifiers (not shown) connected to the respective coils in the data collecting section 24 is designed to be as low as possible.

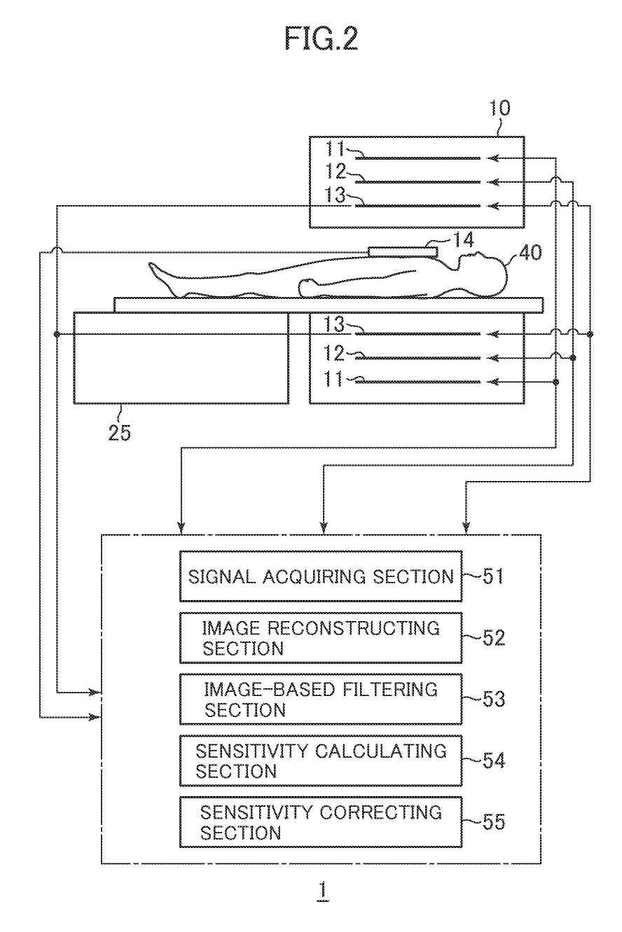

FIG. 2 is a functional block diagram functionally representing a main portion of the magnetic resonance imaging apparatus 1. The magnetic resonance imaging apparatus 1 comprises a signal acquiring section 51, an image reconstructing section 52, an image-based filtering section 53, a sensitivity calculating section 54, and a sensitivity correcting section 55. It should be noted that these sections 51-55 are implemented by, for example, causing a computer to execute specified programs. The signal acquiring section 51 represents an example of the acquiring means and receiving means in the invention. The image-based filtering section 53 represents an example of the suppressing means in the invention. The sensitivity calculating section 54 represents an example of the calculating means in the invention. The sensitivity correcting section 55 represents an example of the reducing means in the invention.

The signal acquiring section 51 controls several sections to transmit an RF magnetic field to the region to be imaged in the subject and acquire magnetic resonance signals from the region to be imaged by simultaneously receiving them at the body coil section 13 and surface coil section 14.

The image reconstructing section 52 reconstructs a first image based on the received signals from the body coil section 13 and a second image based on the received signals from the surface coil section 14. The images are reconstructed by, for example, applying inverse Fourier transformation to data in k-space formed by the received signals from the coils.

The image-based filtering section 53 applies an image-based filter to the first image based on the received signals from the body coil section 13 to suppress shading due to B1 inhomogeneity. Usable image-based filters include, for example, an SCIC filter, a homomorphic filter, and an ITK-N4 Bias Field Correction filter, which are designed for correction of an MR image.

The sensitivity calculating section 54 calculates a sensitivity S of the surface coil section 14 based on a filtered image Gb′ obtained by applying an image-based filter to the first image Gb according to the received signals from the body coil section 13 and the second image Gs according to the received signals from the surface coil section 14. The sensitivity S is assumed herein to be determined in the form of a sensitivity map with respect to a pixel value in the second image Gs according to the received signals from the surface coil section 14. The sensitivity S(x, y) for each pixel (x, y) may be calculated by Gs′(x, y)/Gb″(x, y), wherein Gs′(x, y) designates a pixel value of a pixel (x, y) in an image Gs′, which is a degraded version of the second image Gs, and Gb″(x, y) designates a pixel value of a pixel (x, y) in an image Gb″, which is a degraded version of the filtered image Gb′. A degraded version of an image may be obtained by, for example, reconstructing the image using only data in the vicinity of a center of k-space, or applying smoothing processing to the original image.

The sensitivity correcting section 55 uses the calculated sensitivity S to apply sensitivity correction to the second image Gs according to the received signals from the surface coil section 14. The sensitivity correction is achieved by setting, for each pixel (x, y), a value obtained by Gs(x, y)/S(x, y) to a pixel value of that pixel.

Now flow of imaging processing in the magnetic resonance imaging apparatus 1 in accordance with the present embodiment will be described.

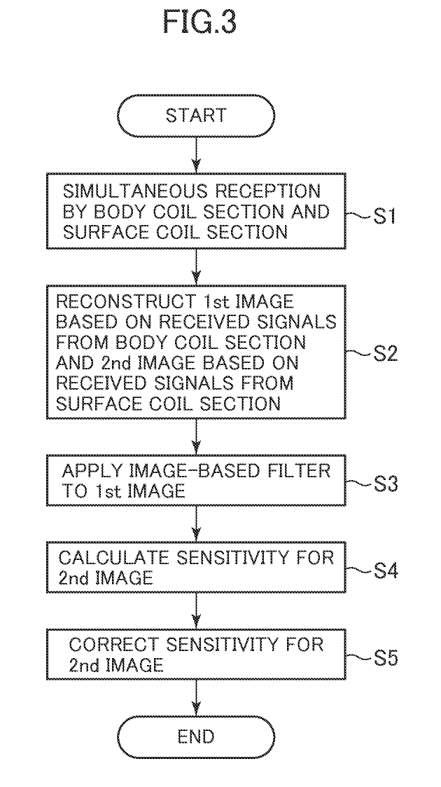

FIG. 3 is a flow chart of imaging processing in the magnetic resonance imaging apparatus 1. For convenience of explanation, let us assume a case in which a region of one prespecified slice in the subject 40 is to be imaged and an image in that slice is to be reconstructed.

At Step S1, an operator places the surface coil section 14 on the subject 40. Then, in response to a command by the operator, the signal acquiring section 51 performs a scan on a predefined slice region SR in a plurality of views so that a main portion in k-space is almost completely filled, and simultaneously receives received signals by the body coil section 13 and surface coil section 14 from the slice region SR in each view. In terms of a pulse sequence, a scan is performed while changing the intensity of the phase encoding pulse to each of a plurality of levels, and received signals are simultaneously received by the two coils in each of the scans.

This gives received signals for the body coil section 13 and those for the channel coils in the surface coil section 14.

At Step S2, the image reconstructing section 52 reconstructs a first image Gb based on the received signals from the body coil section 13. The image reconstructing section 52 also reconstructs a second image Gs based on the received signals from the surface coil section 14. The second image Gs is a combined image formed by combining a plurality of channel images based on the received signals from the channel coils constituting the surface coil section 14.

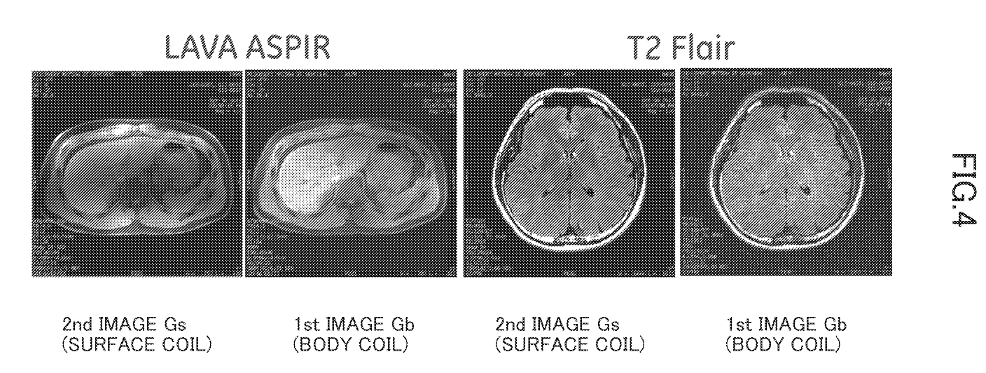

FIG. 4 depicts exemplary first images according to received signals from the body coil section and exemplary second images according to received signals from the surface coil section. Images on the left side represent exemplary tomographic images of an abdomen by a LAVA ASPIR (abdominal gradient echo) imaging technique. Images on the right side represent exemplary tomographic images of a head by a T2 Flair imaging technique.

At Step S3, the image-based filtering section 53 applies an image-based filter to the first image Gb by the body coil section 13 to suppress shading due to B1 inhomogeneity in the first image Gb.

At Step S4, the sensitivity calculating section 54 calculates a sensitivity S representing a sensitivity map with respect to a pixel value in the second image Gs by the surface coil section 14 based on the second image Gs and a filtered image Gb′.

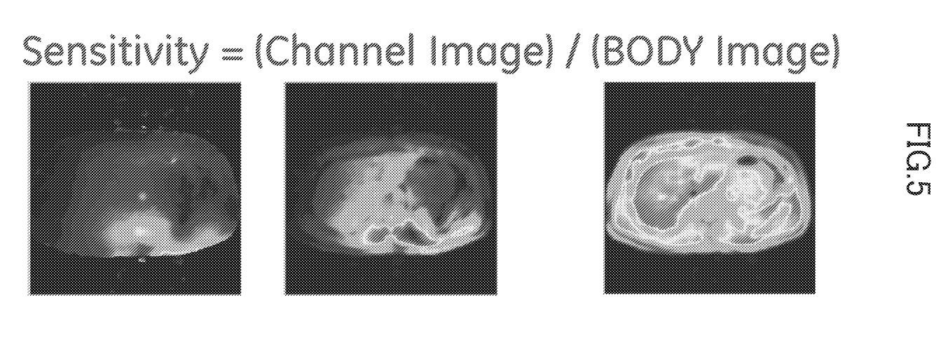

A conceptual representation of the processing of calculating a sensitivity is shown in FIG. 5. The drawing conceptually shows the processing of calculating a sensitivity for a channel image for a certain channel by dividing a degraded version of the channel image by a degraded version of the filtered image.

At Step S5, the sensitivity correcting section 55 applies sensitivity correction to the second image Gs by the surface coil section 14. In particular, the second image Gs is divided by its sensitivity S. Thus, a combined image having homogeneous sensitivity may be obtained as intended image.

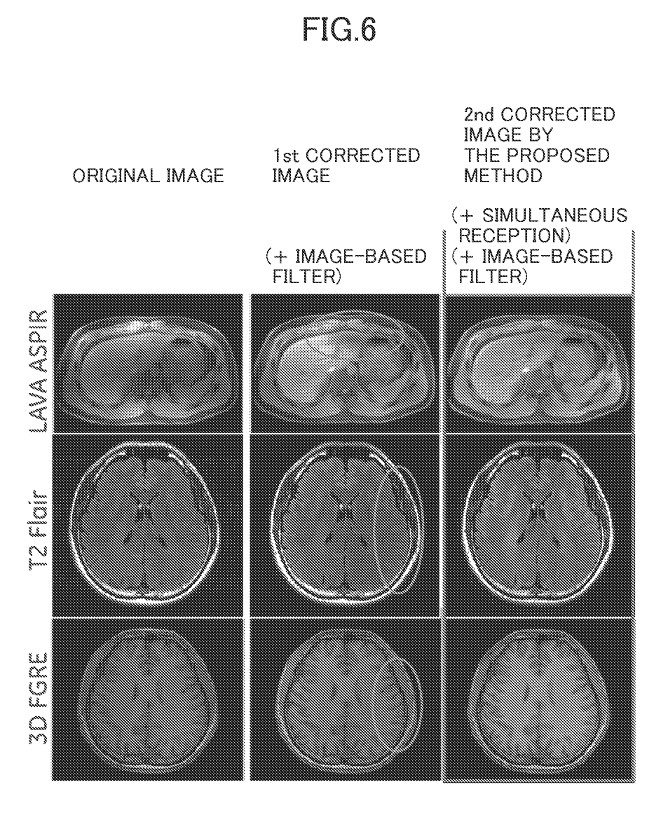

FIG. 6 shows exemplary results of shading suppression by the technique in the present embodiment. In FIG. 6, the upper row lists abdominal tomographic images by the LAVA ASPIR imaging technique. The middle row lists head tomographic images by the T2 Flair imaging technique. The lower row lists head tomographic images by a 3D FGRE (three-dimensional fast gradient echo) imaging technique. On the other hand, the left column lists uncorrected original images based on received signals from the surface coil section in a main scan. The central column lists first corrected images each obtained by dividing an image according to received signals from the surface coil section in the main scan by an image according to received signals from the body coil section in the calibration scan to calculate a sensitivity, and using the sensitivity to apply sensitivity correction to the image from the surface coil section. The right column lists second corrected images each obtained by applying an image-based filter to an image according to received signals from the body coil section from simultaneous reception in the main scan to obtain a shading-suppressed image, dividing an image according to received signals from the surface coil section from the simultaneous reception in the main scan by the shading-suppressed image to calculate a sensitivity, and using the sensitivity to apply sensitivity correction to an image by the surface coil section.

For the images by the LAVA imaging technique, shading is noticeably observed in the original image due to sensitivity unevenness in the surface coil section and inhomogeneity in the transmission magnetic field. In the first corrected image, while shading is improved as compared with the original image, shading resulting from a difference in shading due to B1 inhomogeneity between the calibration scan and main scan is slightly observed (see an area surrounded by an ellipse). In the second corrected image, the shading is moderately suppressed. For the images by the T2 Flair and 3D FGRE imaging techniques, again, shading is noticeably observed in the original image due to sensitivity unevenness in the surface coil section and B1 inhomogeneity. In the first corrected image, while shading is improved as compared with the original image, shading resulting from a difference in shading due to B1 inhomogeneity between the calibration scan and main scan appears as a difference between the left and right (see an area surrounded by an ellipse). In the second corrected image, the left-and-right difference is almost completely removed.

As described above, according to the present embodiment, since magnetic resonance signals are simultaneously received by a body coil and a surface coil, subject misregistration between images based on received signals from these coils can be eliminated. Moreover, scan conditions are the same between received signals from these coils. Since subject misregistration is eliminated, shading due to B1 inhomogeneity appears in substantially the same manner between images based on received signals from these coils. From these facts, sensitivity correction can be appropriately achieved and shading in an intended image generated due to B1 inhomogeneity may be effectively suppressed by an image-based filter.

Moreover, since a separate calibration scan is not needed, the imaging time may be reduced. The need for care of subject misregistration between received signals from the body coil section in the calibration scan and those from the surface coil section is also eliminated.

Furthermore, since shading in an intended image may be robustly suppressed, unlike in conventional techniques, a region to be imaged and/or an application to be used is not limited by reason of generation of shading in an imaging technique of applying sensitivity correction to an image from a surface coil while referring to an image from a body coil.

The present invention is not limited to the embodiment above, and several modifications may be made without departing from the spirit and scope of the invention.

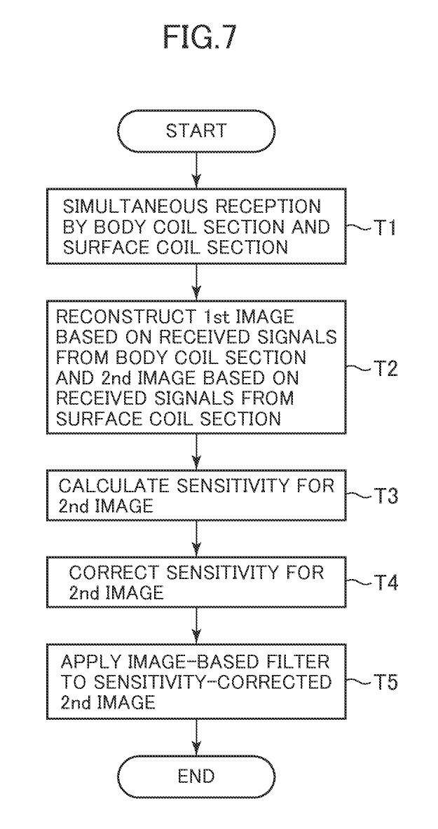

For example, while in this embodiment, an image-based filter is applied to the first image Gb according to received signals from the body coil section 13, an image-based filter may be applied to an image Gs′ obtained by applying sensitivity correction to the second image Gs according to received signals from the surface coil section 14, as shown in FIG. 7. Also by the process, shading in an intended image may be effectively suppressed.

Moreover, for example, a sensitivity-corrected image is obtained in this embodiment by calculating a sensitivity with respect to a pixel value in the second image Gs, which is a combined image of channel images for the surface coil section 14, as sensitivity S, and dividing the second image Gs by the sensitivity S; however, the sensitivity-corrected image may be obtained by calculating a sensitivity with respect to a pixel value in the channel images for the surface coil section 14 as sensitivity S, and substituting the calculated sensitivity for each channel image into a sensitivity term in a combination formula for channel images for obtaining the combined image; for example, a combination formula proposed by Roemer, etc. In this case, a sensitivity for each channel image can be obtained by dividing the channel image according to received signals from each channel by a first image Gb according to received signals from the body coil section 13. It should be noted that the sensitivity is represented by a complex expression comprised of a real part representing the magnitude and an imaginary part representing the phase.

While the embodiment above refers to a magnetic resonance imaging apparatus, a magnetic resonance signal processing apparatus that conducts the processing on received signals as described above, a program for causing a computer to function as such a magnetic resonance signal processing apparatus, and a computer-readable recording medium on which the program is recorded also each constitute one embodiment of the present invention. The recording media include non-transitory media such as a CD-ROM, a USB memory, and a server in a network.

1. A magnetic resonance signal processing method, comprising:
an acquiring step of acquiring magnetic resonance signals simultaneously received at a body coil and a surface coil;
a filtering step of applying image-based filtering for suppressing shading due to B1 inhomogeneity to a first image according to received signals from said body coil;
a calculating step of calculating a sensitivity of said surface coil based on said image-based-filtered first image and a second image according to received signals from said surface coil; and
a correcting step of correcting sensitivity unevenness in said second image using said sensitivity.

2. A magnetic resonance signal processing method, comprising:
an acquiring step of acquiring magnetic resonance signals simultaneously received at a body coil and a surface coil;
a calculating step of calculating a sensitivity of said surface coil based on a first image according to received signals from said body coil and a second image according to received signals from said surface coil;
a correcting step of correcting sensitivity unevenness in said second image using said sensitivity; and
a filtering step of applying image-based filtering for suppressing shading due to B1 inhomogeneity to said corrected second image.

3. A magnetic resonance signal processing apparatus, comprising:
a signal acquiring section for acquiring magnetic resonance signals simultaneously received at a body coil and a surface coil;
an image based filtering section for applying image-based filtering for suppressing shading due to B1 inhomogeneity to a first image according to received signals from said body coil;
a sensitivity calculating section for calculating a sensitivity of said surface coil based on said image-based-filtered first image and a second image according to received signals from said surface coil; and
a sensitivity correcting section for correcting sensitivity unevenness in said second image using said sensitivity.

4. A magnetic resonance signal processing apparatus, comprising:
a signal acquiring section for acquiring magnetic resonance signals simultaneously received at a body coil and a surface coil;
a sensitivity calculating section for calculating a sensitivity of said surface coil based on a first image according to received signals from said body coil and a second image according to received signals from said surface coil;
a sensitivity correcting section on for correcting sensitivity unevenness in said second image using said sensitivity; and
an image based filtering section for applying image-based filtering for suppressing shading due to B1 inhomogeneity to said corrected second image.

5. The magnetic resonance signal processing apparatus as recited in claim 3, wherein:
said second image is a combined image of images from channels in said surface coil;
said sensitivity calculating section calculates a sensitivity with respect to a pixel value in said combined image; and
said sensitivity correcting section corrects sensitivity unevenness in said second image by dividing said second image by said sensitivity.

6. The magnetic resonance signal processing apparatus as recited in claim 3, wherein:
said second image is a combined image of images from channels in said surface coil;
said sensitivity calculating section calculates a sensitivity with respect to a pixel value in said images from channels by a complex expression; and
said sensitivity correcting section corrects sensitivity unevenness in said second image by substituting said sensitivity for said images from channels by a complex expression into a combination formula for said images from channels for obtaining said combined image.

7. The magnetic resonance signal processing apparatus as recited claim 3, wherein said image-based filter comprises any one of an SCIC (Surface Coil Intensity Correction) filter, a homomorphic filter, and an ITK-N4 Bias Field Correction filter.

8. The magnetic resonance signal processing apparatus as recited in claim 3, wherein the intensity of a static magnetic field in simultaneously receiving said magnetic resonance signals is substantially 3 teslas or more.

9. A magnetic resonance apparatus, comprising:
a signal receiving section for simultaneously receiving magnetic resonance signals by a body coil and a surface coil;
an image based filtering section for applying image-based filtering for suppressing shading due to B1 inhomogeneity to a first image according to received signals from said body coil;
a sensitivity calculating section for calculating a sensitivity of said surface coil based on said image-based-filtered first image and a second image according to received signals from said surface coil; and
a sensitivity correcting section for correcting sensitivity unevenness in said second image using said sensitivity.

10. A magnetic resonance apparatus, comprising:
a signal receiving section for simultaneously receiving magnetic resonance signals by a body coil and a surface coil;
a sensitivity calculating section for calculating a sensitivity of said surface coil based on a first image according to received signals from said body coil and a second image according to received signals from said surface coil;
a sensitivity correcting section for correcting sensitivity unevenness in said second image using said sensitivity; and
an image based filtering section for applying image-based filtering for suppressing shading due to B1 inhomogeneity to said corrected second image.

11. The magnetic resonance apparatus as recited in claim 9, wherein:
said second image is a combined image of images from channels in said surface coil;
said sensitivity calculating section calculates a sensitivity with respect to a pixel value in said combined image; and
said sensitivity correcting section corrects sensitivity unevenness in said second image by dividing said second image by said sensitivity.

12. The magnetic resonance apparatus as recited in claim 10, wherein:
said second image is a combined image of images from channels in said surface coil;
said sensitivity calculating section calculates a sensitivity with respect to a pixel value in said images from channels by a complex expression; and
said sensitivity correcting section corrects sensitivity unevenness in said second image by substituting said sensitivity for said images from channels by a complex expression into a combination formula for said images from channels for obtaining said combined image.

13. The magnetic resonance apparatus as recited in claim 9, wherein said image-based filter comprises any one of an SCIC (Surface Coil Intensity Correction) filter, a homomorphic filter, and an ITK-N4 Bias Field Correction filter.

14. The magnetic resonance apparatus as recited in claim 9, wherein the intensity of a static magnetic field in simultaneously receiving said magnetic resonance signals is substantially 3 teslas or more.

15. (canceled)
